(19) United States
(12) Patent Application Publication
(10) Pub. No.: US 2025/0348116 A1
(43) Pub. Date: Nov. 13, 2025

(54) DISPLAY DEVICE

(71) Applicants: Samsung Display Co., LTD., Yongin-si (KR); UIF (University Industry Foundation), Yonsei University, Seoul (KR)

(72) Inventors: TAEWOONG KIM, Yongin-si (KR); Jong Hyun AHN, Seoul (KR); JIN HEE NA, Yongin-si (KR); Beomjin KIM, Seoul (KR); Heechang SHIN, Seoul (KR); Seokmin YUN, Seoul (KR)

(21) Appl. No.: 19/088,272

(22) Filed: Mar. 24, 2025

(30) Foreign Application Priority Data
May 9, 2024 (KR) 10-2024-0060955

(51) Int. Cl. G06F 1/16

(52) U.S. Cl. CPC G06F 1/1652; G06F 1/1656

(57) ABSTRACT

A display device includes: a display panel, an upper member disposed above the display panel, a first auxetic structure disposed below the display panel, and a second auxetic structure disposed below the first auxetic structure. First unit cells of the first auxetic structure have a smaller pitch than second unit cells of the second auxetic structure.

This application claims priority to Korean Patent Application No. 10-2024-0060955, filed on May 9, 2024, and all the benefits accruing therefrom under 35 U.S.C. § 119, the content of which in its entirety is herein incorporated by reference.

### BACKGROUND

Embodiments of the present disclosure described herein relate to a display device, and more particularly, relate to a flexible display device.

Electronic devices, such as smart phones, tablet computers, notebook computers, car navigation units, smart televisions, and the like, are being developed. The electronic devices include a display device to provide information.

Various types of display devices are being developed to satisfy users' UX/UI. Among them, the development of flexible display devices, such as foldable display devices and rollable display devices, has been promoted.

### SUMMARY

Embodiments of the present disclosure provide a display device with improved impact resistance and reduced defects.

According to an embodiment, a display device includes a display panel, an upper member disposed above the display panel, a first auxetic structure that is disposed below the display panel and that includes first unit cells, and a second auxetic structure that is disposed below the first auxetic structure and that includes second unit cells. The first unit cells of the first auxetic structure have a smaller pitch than the second unit cells of the second auxetic structure.

The display device may further include an adhesive layer disposed between the first auxetic structure and the second auxetic structure to bond the first auxetic structure and the second auxetic structure. The adhesive layer may have a lower elastic modulus than each of the first auxetic structure and the second auxetic structure.

The display panel may provide a display surface defined by a first direction and a second direction. In a first mode of the display device, the display surface may provide a flat surface, and in a second mode of the display device, at least a partial area of the display surface may provide a curved surface having a certain curvature with respect to a reference axis.

The display device may further include a support layer disposed below the second auxetic structure. The support layer may include a plurality of support sticks parallel to the reference axis. In the first mode, the plurality of support sticks may be arranged in a direction crossing the reference axis.

The first unit cells may have each the same shape as and a different area from each the second unit cells.

The first auxetic structure may include a first line, and the second auxetic structure may include a second line. The first line may define the first unit cells, each of which defines an opening therein.

The first line may have substantially the same line width and thickness as the second line.

The second line may overlap the openings of at least some of the first unit cells in a plan view.

The display panel may include a display area where a pixel is disposed and a non-display area where a pixel is not disposed. The first auxetic structure and the second auxetic structure may overlap an entirety of the display area in a plan view.

The display device may further include an adhesive layer disposed below the display panel. The first auxetic structure and the second auxetic structure may be impregnated in the adhesive layer.

According to an embodiment, a display device includes a display panel, an upper member disposed above the display panel, a first auxetic structure disposed below the display panel, and a second auxetic structure disposed below the first auxetic structure. The second auxetic structure has a lower elastic modulus than the first auxetic structure.

The first auxetic structure may have an elastic modulus of 200 megapascals (MPa) to 1 gigapascal (GPa), and the second auxetic structure may have an elastic modulus of 20 MPa to 200 MPa.

The display device may further include an adhesive layer disposed between the first auxetic structure and the second auxetic structure to bond the first auxetic structure and the second auxetic structure. The adhesive layer may have a lower elastic modulus than each of the first auxetic structure and the second auxetic structure.

The display device may further include a support layer disposed below the second auxetic structure. The support layer may include a plurality of support sticks. The plurality of support sticks may be arranged in a direction crossing a direction in which the plurality of support sticks extend.

The first auxetic structure may include a first line, and the second auxetic structure may include a second line. The first line may define first unit cells, each of which defines a first opening therein. The second line may define second unit cells, each of which defines a second opening therein.

The first unit cells may have each the same shape as and a different area from and each the second unit cells. The first line may have substantially the same line width and thickness as the second line.

The second line may overlap the first openings of at least some of the first unit cells in a plan view.

The display panel may include a display area where a pixel is disposed and a non-display area where a pixel is not disposed.

The first auxetic structure and the second auxetic structure may overlap an entirety of the display area in a plan view.

The display device may further include an adhesive layer disposed below the display panel. The first auxetic structure and the second auxetic structure may be impregnated in the adhesive layer.

### BRIEF DESCRIPTION OF THE FIGURES

The above and other aspects and features of the present disclosure will become apparent by describing in detail embodiments thereof with reference to the accompanying drawings.

FIGS. 1A and 1B are perspective views of a foldable display device according to an embodiment of the present disclosure.

FIGS. 2A and 2B are sectional views of a rollable display system including a rollable display device according to an embodiment of the present disclosure.

FIG. 3 is a sectional view of a display device according to an embodiment of the present disclosure.

FIG. 4A is a sectional view of a display panel according to an embodiment of the present disclosure.

FIG. 4B is a perspective view of a support layer according to an embodiment of the present disclosure.

FIG. 5 is a perspective view of a stress control layer according to an embodiment of the present disclosure.

FIG. 6A is a plan view illustrating a first auxetic structure according to an embodiment of the present disclosure.

FIG. 6B is a plan view illustrating a second auxetic structure according to an embodiment of the present disclosure.

FIG. 7A is a plan view illustrating a state in which the first auxetic structure and the second auxetic structure overlap each other according to an embodiment of the present disclosure.

FIG. 7B is a plan view illustrating one unit cell of the second auxetic structure and unit cells of the first auxetic structure overlapping the one unit cell according to an embodiment of the present disclosure.

FIG. 8 is a sectional view illustrating a neutral plane formed in the display device in a second mode according to an embodiment of the present disclosure.

FIG. 9A is a plan view illustrating the first auxetic structure according to an embodiment of the present disclosure.

FIG. 9B is a plan view illustrating the second auxetic structure according to an embodiment of the present disclosure.

FIG. 10A is a plan view illustrating the first auxetic structure according to an embodiment of the present disclosure.

FIG. 10B is a plan view illustrating the second auxetic structure according to an embodiment of the present disclosure.

FIG. 11 is a sectional view of the display device according to another embodiment of the present disclosure.

FIG. 12 is a block diagram illustrating an electronic device according to an embodiment.

### DETAILED DESCRIPTION

In this specification, when a component (or, an area, a layer, a part, etc.) is referred to as being “on”, “connected to” or “coupled to” another component, this means that the component may be directly on, connected to, or coupled to the other component or a third component may be present therebetween.

Identical reference numerals refer to identical components. Additionally, in the drawings, the thicknesses, proportions, and dimensions of components are exaggerated for effective description. As used herein, the term “and/or” includes all of one or more combinations defined by related components.

Terms such as first, second, and the like may be used to describe various components, but the components should not be limited by the terms. The terms may be used only for distinguishing one component from other components. For example, without departing the scope of the present disclosure, a first component may be referred to as a second component, and similarly, the second component may also be referred to as the first component. The terms of a singular form may include plural forms unless otherwise specified.

In addition, terms such as “below”, “under”, “above”, and “over” are used to describe a relationship between components illustrated in the drawings. The terms are relative concepts and are described based on directions illustrated in the drawing.

It should be understood that terms such as “comprise”, “include”, and “have”, when used herein, specify the presence of stated features, numbers, steps, operations, components, parts, or combinations thereof, but do not preclude the presence or addition of one or more other features, numbers, steps, operations, components, parts, or combinations thereof.

Unless otherwise defined, all terms used herein, including technical or scientific terms, have the same meanings as those generally understood by those skilled in the art to which the present disclosure pertains. Such terms as those defined in a generally used dictionary are to be interpreted as having meanings equal to the contextual meanings in the relevant field of art, and are not to be interpreted as having ideal or excessively formal meanings unless clearly defined as having such in the present application.

“Substantially the same” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “substantially the same” can mean within one or more standard deviations, or within +10%, 5% or 2% of the stated value. Hereinafter, embodiments of the present disclosure will be described with reference to the accompanying drawings.

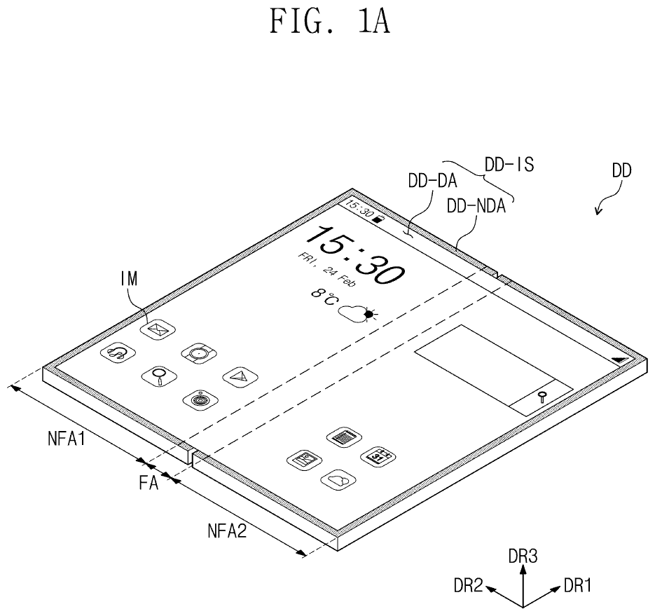

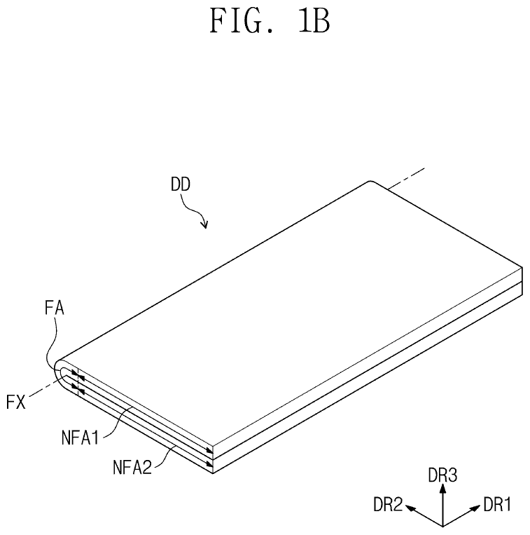

FIGS. 1A and 1B are perspective views of a foldable display device DD according to an embodiment of the present disclosure. FIGS. 2A and 2B are sectional views of a rollable display system RDS including a rollable display device DD according to an embodiment of the present disclosure.

FIGS. 1A and 1B illustrate the foldable display device DD as an example of a flexible display device, and FIGS. 2A and 2B illustrate the rollable display system RDS including the rollable display device DD as an example of a flexible display device. However, without being limited thereto, the present disclosure may be applied to other display devices such as a slidable display device.

FIG. 1A illustrates an unfolded state (a first mode) of the foldable display device DD. A display surface DD-IS is parallel to a plane defined by a first direction DR1 and a second direction DR2. The normal direction of the display surface DD-IS, that is, a thickness direction of the foldable display device DD is indicated by a third directional axis DR3. Front surfaces (or, upper surfaces) and rear surfaces (or, lower surfaces) of members may be distinguished from each other based on the third direction DR3. Hereinafter, the first to third directions are directions indicated by first to third directional axes DR1, DR2, and DR3, respectively, and refer to the same reference numerals.

As illustrated in FIG. 1A, the display surface DD-IS includes a display area DD-DA where an image IM is displayed and a non-display area DD-NDA adjacent to the display area DD-DA. Pixels of a display panel are disposed in the display area DD-DA, but are not disposed in the non-display area DD-NDA. Accordingly, the non-display area DD-NDA is an area where an image is not displayed. In FIG. 1, icon images are illustrated as an example of the image IM. For example, the display area DD-DA may have a quadrangular shape. The non-display area DD-NDA may surround the display area DD-DA. However, without being limited thereto, the shape of the display area DD-DA and the shape of the non-display area DD-NDA may be modified.

FIG. 1B illustrates a folded state (a second mode) of the foldable display device DD. As illustrated in FIG. 1B, the foldable display device DD may include a plurality of areas defined depending on operation types. The foldable display device DD may include a folding area FA folded about a folding axis FX and a first flat area NFA1 and a second flat area NFA2 that are adjacent to the folding area FA. In this embodiment, the folding axis FX may be parallel to the first direction DR1. The folding area FA is an area that substantially forms a curvature. The folding area FA provides the curved display surface DD-IS in the second mode. The folding axis FX may be a reference axis of the folding area FA.

In this embodiment, the foldable display device DD in which the folding axis FX is defined parallel to the first direction DR1 of the display device DD is illustrated as an example. However, without being limited thereto, the folding axis FX may be parallel to another direction.

As illustrated in FIGS. 1A and 1B, the foldable display device DD may be folded in an inner-folding or inner-bending manner such that the display surface DD-IS of the first flat area NFA1 and the display surface DD-IS of the second flat area NFA2 face each other. In an embodiment of the present disclosure, the foldable display device DD may be folded in an outer-folding or outer-bending manner such that the display surface DD-IS is exposed to the outside.

In an embodiment of the present disclosure, the foldable display device DD may include a plurality of folding areas FA. In addition, the folding area FA may be defined to correspond to the form in which a user manipulates the foldable display device DD. For example, the folding area FA, when viewed from above the plane (i.e., plan view), may be defined in a diagonal direction crossing the first direction DR1 and the second direction DR2. The area of the folding area FA may be determined depending on a radius of curvature without being fixed.

In an embodiment of the present disclosure, the foldable display device DD may be configured such that an inner-folding operation and an outer-folding operation are mutually repeated in the unfolded state. However, the present disclosure is not limited thereto. In an embodiment of the present disclosure, the foldable display device DD may be configured to select one of an unfolding operation, an inner-folding operation, and an outer-folding operation.

Referring to FIGS. 2A and 2B, the rollable display device DD may be accommodated in a housing HS of the rollable display system RDS and may enter and exit the housing HS through an opening HS-OP. One end of the rollable display device DD may be connected to a handle HND. The rollable display device DD may be guided by a support part SUP of the rollable display system RDS. The support part SUP may include an assembly of support frames that are withdrawn in stages during an unrolling operation. The roller ROL of the rollable display system RDS may have a shape extending in the first direction DR1 and may rotate about a rolling axis. The rolling axis may be a reference axis of the rollable display device DD.

FIG. 2A illustrates an unrolled state (a first mode) of the rollable display device DD. FIG. 2B illustrates a rolled state (a second mode) of the rollable display device DD. When the rollable display device DD is unrolled in the first mode, a portion of the rollable display device DD exposed from the housing HS may provide a flat display surface DD-IS. At least a portion of the rollable display device DD disposed in the housing HS in the first mode or the second mode substantially forms a curvature. The portion of the rollable display device DD that forms the curvature provides a curved display device DD-IS.

According to the present disclosure, a stress control layer that will be described below may be disposed to overlap at least the area of the rollable display device DD that provides the curved display surface. For example, the stress control layer may be disposed to entirely overlap the display area DD-DA of the foldable display device DD of FIG. 1A. The stress control layer can have an area larger than the display area DD-DA of the foldable display device DD. Since the stress control layer is disposed in the area that provides the curved display surface, the stress control layer may reduce stress caused by mechanical deformation such as repetitive folding or rolling of the display device.

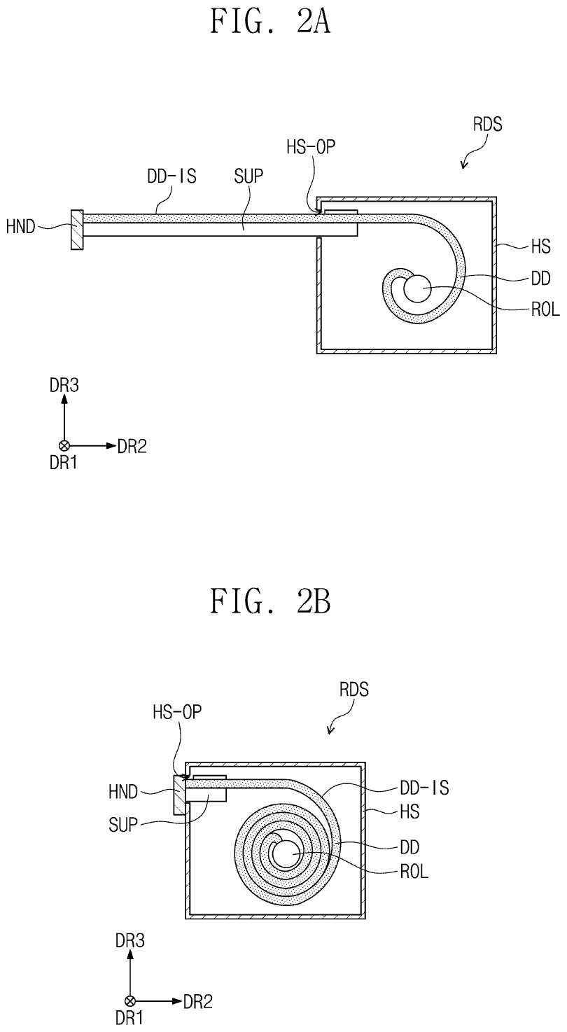

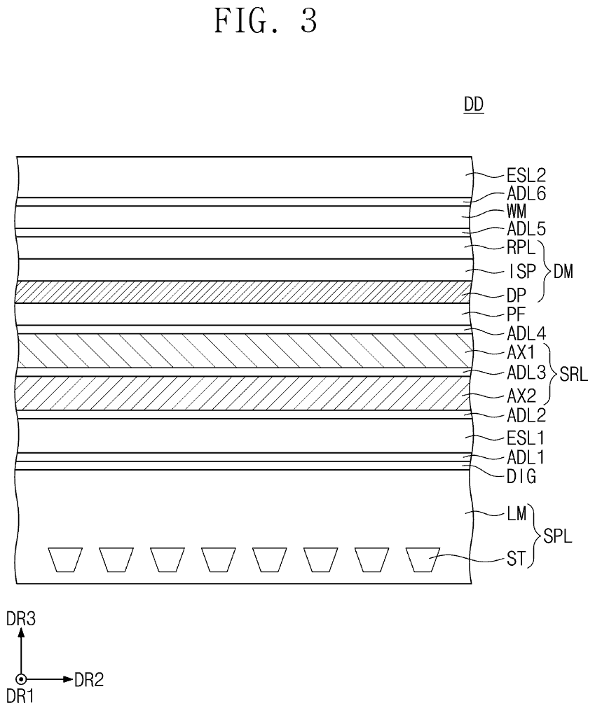

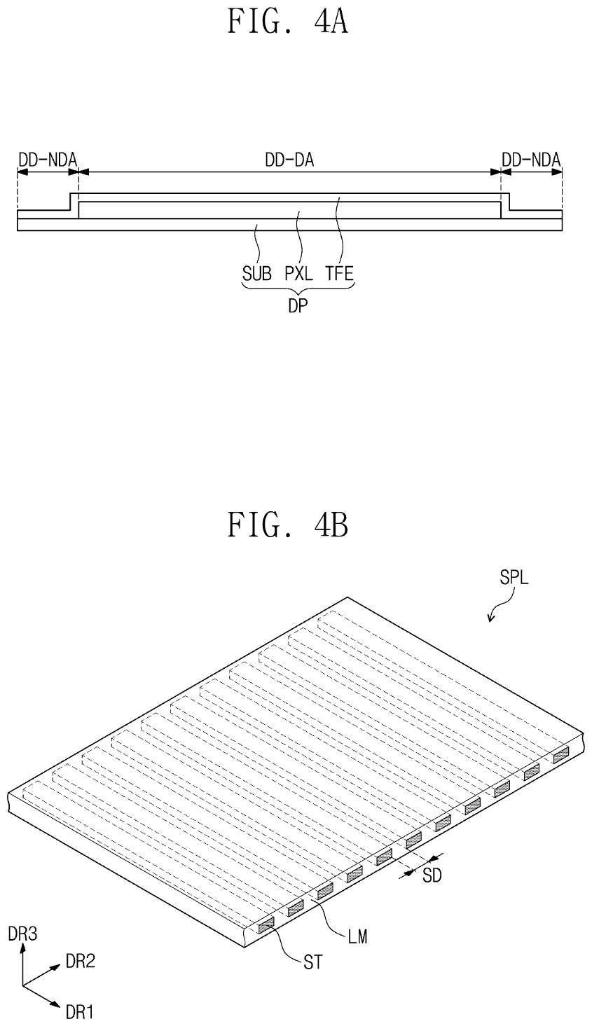

FIG. 3 is a sectional view of a display device DD according to an embodiment of the present disclosure. FIG. 4A is a sectional view of a display panel DP according to an embodiment of the present disclosure. FIG. 4B is a perspective view of a support layer SPL according to an embodiment of the present disclosure.

The display device DD illustrated in FIG. 3 may be the foldable display device DD illustrated in FIGS. 1A and 1B or the rollable display device DD illustrated in FIGS. 2A and 2B. The display device DD may not include some of the components illustrated in FIG. 3 that will be described below.

Referring to FIG. 3, the display device DD according to an embodiment of the present disclosure may include the support layer SPL, a digitizer DIG, a first elastic layer ESL1, a stress control layer SRL, a display panel protection layer PF, a display module DM, a window WM, and a second elastic layer ESL2. In addition, the display device DD may further include first to sixth adhesive layers ADL1 to ADL6 disposed between the components of the display device DD to bond the components. The components disposed above the display module DM (specifically, the display panel DP) may be defined as an upper member, and the components disposed below the display module DM (specifically, the display panel DP) may be defined as a lower member. The upper member may include the window WM and the second elastic layer ESL2. The lower member may include the support layer SPL, the digitizer DIG, the first elastic layer ESL1, the stress control layer SRL, and the display panel protection layer PF.

According to an embodiment of the present disclosure, at least one of the support layer SPL, the digitizer DIG, the first elastic layer ESL1, the display panel protection layer PF, the window WM, and the second elastic layer ESL2 may be omitted. In addition, it may be understood by those skilled in the art that the display device DD according to an embodiment of the present disclosure may further include other general-purpose components other than the components in FIG. 3.

The support layer SPL may be disposed below the display panel DP and may support the display panel DP. The digitizer DIG may be disposed below the display panel DP and may sense an external magnetic field signal. The position of the digitizer DIG may be changed.

The first elastic layer ESL1 may be disposed above the support layer SPL and may include an elastomer. For example, the first elastic layer ESL1 may include at least one of thermoplastic polyurethane, silicone, thermoplastic rubbers, elastolefin, thermoplastic olefin, polyamide, polyether block amide, synthetic polyisoprene, polybutadiene, chloroprene rubber, butyl rubber, styrene-butadiene, epichlorohydrin rubber, polyacrylic rubber, silicone rubber, fluorosilicone rubber, fluoroelastomers, ethylene-vinyl acetate, and polydimethylsiloxane (“PDMS”).

The stress control layer SRL may be disposed between the display panel DP and the support layer SPL. The stress control layer SRL may be bonded to the upper surface of the first elastic layer ESL1 by the second adhesive layer ADL2. The stress control layer SRL may include a first auxetic structure AX1 and a second auxetic structure AX2 disposed on different layers from each other. The stress control layer SRL may include the third adhesive layer ADL3 that couples the first auxetic structure AX1 and the second auxetic structure AX2. The third adhesive layer ADL3 may include a resin or a pressure sensitive adhesive (“PSA”) sheet.

The third adhesive layer ADL3 may have a lower elastic modulus than each of the first auxetic structure AX1 and the second auxetic structure AX2. The third adhesive layer ADL3 may have an elastic modulus of 1 MPa or less. For example, the third adhesive layer ADL3 may have an elastic modulus of 100 kilopascals (Kpa) to 1 MPa, more specifically, an elastic modulus of 200 KPa to 500 KPa.

The first auxetic structure AX1 and the second auxetic structure AX2 may have a negative Poisson's ratio that enables elongation in a biaxial direction. The first auxetic structure AX1 may have a Poisson's ratio of −0.9 to −0.1. The second auxetic structure AX2 may have a Poisson's ratio of −0.9 to −0.1. However, the Poisson's ratios of the first auxetic structure AX1 and the second auxetic structure AX2 are not limited thereto. As the first auxetic structure AX1 and the second auxetic structure AX2 have negative Poisson's ratios close to 0, elongation characteristics and restoration characteristics may be improved.

The stress control layer SRL having a two-layer structure according to this embodiment may improve the flexibility of the display device DD. Here, high flexibility may mean that the display device DD is easily deformed (e.g., by a small external force) in the process of changing from the first mode to the second mode described with reference to FIGS. 1A to 2B and the display device DD is easily recovered in the process of changing from the second mode to the first mode.

The first auxetic structure AX1 and the second auxetic structure AX2 may include a non-magnetic material that does not react to a magnetic field. When the first auxetic structure AX1 and the second auxetic structure AX2 are formed of a non-magnetic material, the first auxetic structure AX1 and the second auxetic structure AX2 may not obstruct an operation of the digitizer DIG that recognizes a user input using a magnetic field. For example, the first auxetic structure AX1 and the second auxetic structure AX2 may include stainless steel.

The stress control layer SRL may increase the restoration characteristics of the display device DD and may improve the surface quality and the impact resistance of the display device DD. Detailed description of the stress control layer SRL will be given below.

The display module DM may include the display panel DP, an input sensor ISP, and an anti-reflective layer RPL. The display module DM may generate an image. The display module DM may sense a user input through the input sensor ISP. It is sufficient for the display module DM to include the display panel DP, and at least one of the input sensor ISP and the anti-reflective layer RPL may be omitted.

The display panel DP may be a flexible display panel. The display panel DP according to an embodiment of the present disclosure may be an emissive display panel, but is not particularly limited. For example, the display panel DP may be an organic light emitting display panel or an inorganic light emitting display panel. An emissive layer of the organic light emitting display panel may include an organic luminescent material. An emissive layer of the inorganic light emitting display panel may include quantum dots and/or quantum rods.

The input sensor ISP may be disposed on the display panel DP. The input sensor ISP may include a plurality of sensor electrodes (not illustrated) for sensing an external input in a capacitance type. The input sensor ISP may be directly formed (or, disposed) on the display panel DP. However, without being limited thereto, the input sensor ISP may be manufactured as a panel separate from the display panel DP and may be attached to the display panel DP by an adhesive layer.

The anti-reflective layer RPL may be directly formed (or, disposed) on the input sensor ISP. However, without being limited thereto, the anti-reflective layer RPL may be coupled to the input sensor ISP by an adhesive layer. The anti-reflective layer RPL may be defined as a film for preventing reflection of external light. The anti-reflective layer RPL may decrease the reflectance of external light incident toward the display panel DP from above the display device DD.

When external light travelling toward the display panel DP is reflected from the display panel DP and provided back to the user, the user may visually recognize the external light as in a mirror. To prevent such a phenomenon, the anti-reflective layer RPL may include a plurality of color filters that display the same colors as those of the pixels of the display panel DP. The color filters may filter the external light into the same colors as those of the pixels. In this case, the external light may not be visible to the user.

In an embodiment of the present disclosure, the anti-reflective layer RPL may include a polarizer film for decreasing the reflectance of external light. The polarizer film may include a phase retarder and/or a polarizer. The color filters may be directly formed on the input sensor ISP. The polarizer film may be attached to the input sensor ISP by an adhesive layer.

The display panel protection layer PF may be disposed on the lower surface of the display panel DP and may protect the display panel DP from impact. The display panel protection layer PF may be bonded to the stress control layer SRL by the fourth adhesive layer ADL4. The display panel protection layer PF may have an elastic modulus of 1 GPa to 10 GPa. The display panel protection layer PF may have a thickness of 10 micrometers (μm) to 100 μm.

The window WM may be disposed on the anti-reflective layer RPL. The window WM may be bonded to the anti-reflective layer RPL by the fifth adhesive layer ADL5. The window WM may protect the display panel DP, the input sensor ISP, and the anti-reflective layer RPL from external scratches and impacts.

The second elastic layer ESL2 may be bonded to the window WM by the sixth adhesive layer ADL6. The second elastic layer ESL2 may be disposed above the window WM and may include an elastomer. For example, the second elastic layer ESL2 may include one of the above-described materials that are able to be selected as the first elastic layer ESL1.

Referring to FIG. 4A, the display panel DP may include a base layer BL, a pixel layer PXL, and a thin film encapsulation layer TFE. The base layer SUB may include a display area DD-DA and a non-display area DD-NDA around the display area DD-DA. The base layer SUB may include a flexible plastic substrate. For example, the base layer SUB may include a flexible plastic material such as polyimide (“P1”).

The pixel layer PXL may overlap the display area DD-DA. The pixel layer PXL may include a plurality of pixels, and each of the pixels may include a pixel driving circuit and a light emitting element. The thin film encapsulation layer TFE may include at least two inorganic layers and an organic layer between the inorganic layers. The inorganic layers may include an inorganic material and may protect the pixel layer PXL from moisture/oxygen. The organic layer may include an organic material and may protect the pixel layer PXL from foreign matter such as dust particles.

Referring to FIG. 4B, the support layer SPL may include support sticks ST and an outer layer LM. The support sticks ST may extend in the same direction as the reference axis. The plurality of support sticks ST may be arranged in parallel in the second direction DR2. Support sticks ST adjacent to each other among the plurality of support sticks ST are spaced apart from each other to prevent interference between the adjacent support sticks ST in the second mode of FIG. 1B or 2B. The area between the adjacent support sticks ST may be defined as a separation area SD. The separation distances between the plurality of support sticks ST may be the same, but are not necessarily limited thereto.

The plurality of support sticks ST may have a rigid property. For example, the plurality of support sticks ST may include metal. The support sticks ST may include aluminum, stainless steel, or invar. Furthermore, the support sticks ST may include metal that is attracted to a magnet.

Although the plurality of support sticks ST having a rectangular cross-section are illustrated as an example in FIG. 4B, the present disclosure is not limited thereto. The plurality of support sticks ST may have a trapezoidal cross-section like the support sticks ST of FIG. 3. The plurality of support sticks ST may include a first group of support sticks that form a first layer and a second group of support sticks that are spaced apart from the first group of support sticks in the third direction DR3 and that form a second layer.

The outer layer LM may fix the plurality of support sticks ST spaced apart from each other. The outer layer LM may absorb stress generated by the plurality of support sticks ST when the display device DD (refer to FIG. 3) is repeatedly deformed.

The outer layer LM may include an elastomer having elasticity. For example, the outer layer LM may include at least one of thermoplastic polyurethane, silicone, thermoplastic rubbers, elastolefin, thermoplastic olefin, polyamide, polyether block amide, synthetic polyisoprene, polybutadiene, chloroprene rubber, butyl rubber, styrene-butadiene, epichlorohydrin rubber, polyacrylic rubber, silicone rubber, fluorosilicone rubber, fluoroelastomers, ethylene-vinyl and acetate, polydimethylsiloxane (“PDMS”). However, the material of the outer layer LM is not limited thereto.

When the outer layer LM is not used and the support sticks ST are attached to the lower surface of the display module DM to support the display module DM, the display module DM may be deformed in the spaces between the support sticks ST. For example, when the mode of the display device DD is repeatedly changed (e.g., between FIG. 1A and FIG. 1B or between FIG. 2A and FIG. 2B), the portions of the display module DM that overlap the separation areas SD in a plan view may be deformed. The deformation of the display module DM may be visually recognized as creases. That is, the surface quality of the display device DD may be degraded.

The support sticks ST may have a higher elastic modulus than the outer layer LM. The outer layer LM may have an elastic modulus of 20 KPa to 20 MPa. The support sticks ST may have an elastic modulus of 1 GPa to 200 GPa.

The support sticks ST having a relatively high rigidity may support the display module DM, and the outer layer LM having a relatively high elasticity may provide a flat support surface for the display module DM.

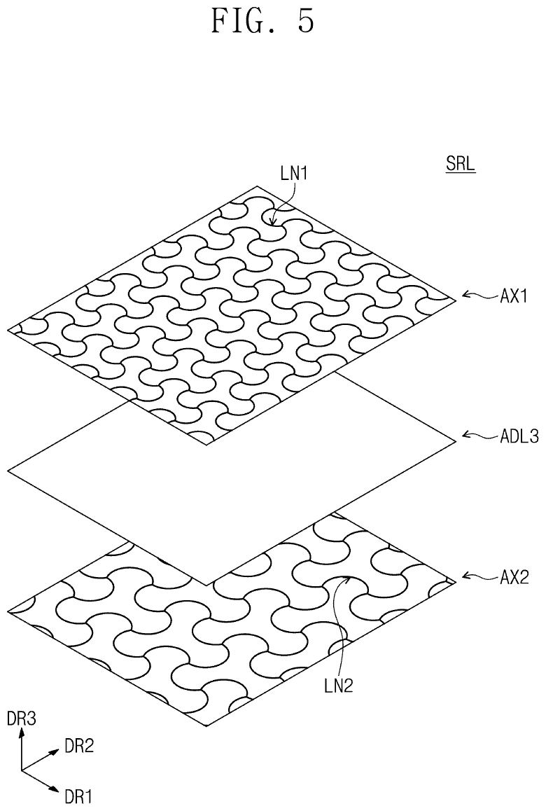

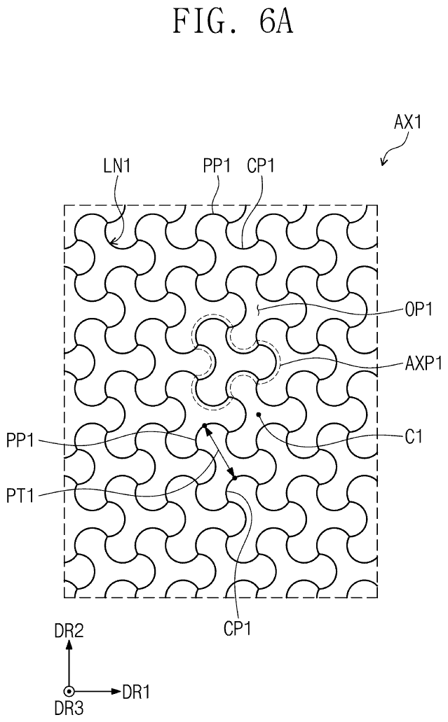

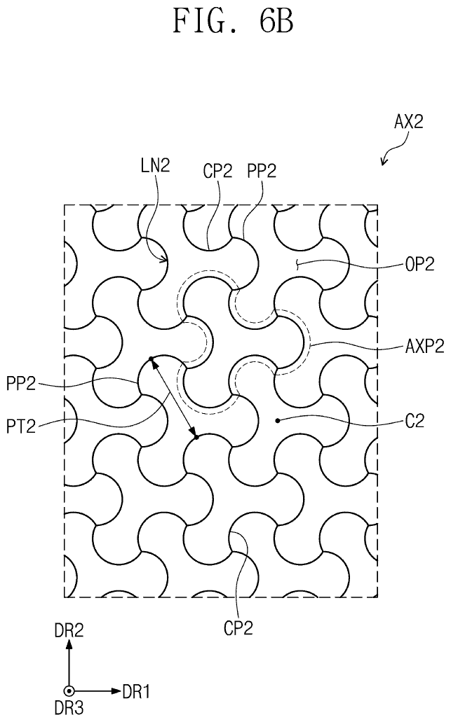

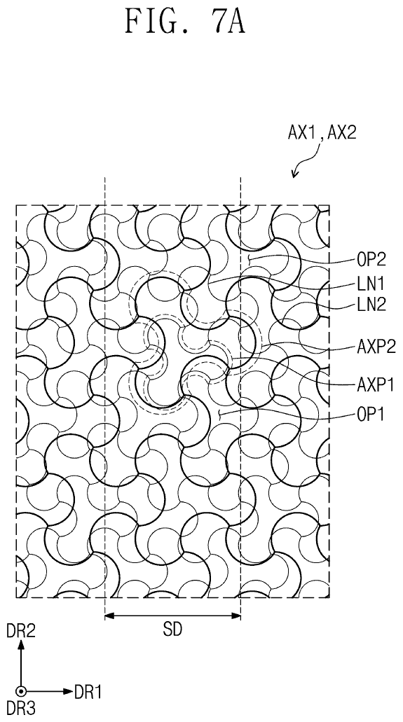

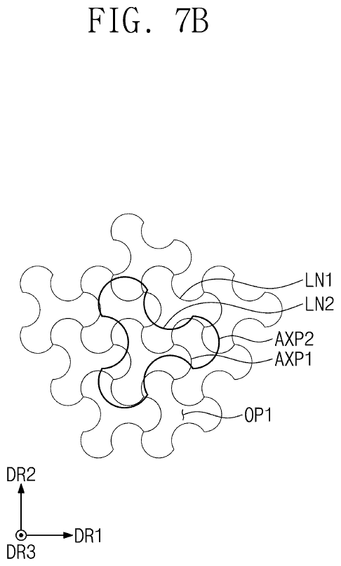

FIG. 5 is a perspective view of the stress control layer SRL according to an embodiment of the present disclosure. FIG. 6A is a plan view illustrating the first auxetic structure AX1 according to an embodiment of the present disclosure. FIG. 6B is a plan view illustrating the second auxetic structure AX2 according to an embodiment of the present disclosure. FIG. 7A is a plan view illustrating a state in which the first auxetic structure AX1 and the second auxetic structure AX2 overlap each other according to an embodiment of the present disclosure. FIG. 7B is a plan view illustrating one unit cell AXP2 of the second auxetic structure AX2 and unit cells AXP1 (or, first auxetic unit cells) of the first auxetic structure AX1 overlapping the one unit cell AXP2 according to an embodiment of the present disclosure. As used herein, the “plan view” is a view in a thickness direction (i.e., DR3) of the display device DD in an unfolded state.

Referring to FIG. 5, the stress control layer SRL may include the first auxetic structure AX1, the third adhesive layer ADL3, and the second auxetic structure AX2.

As illustrated in FIGS. 5 and 6A, the first auxetic structure AX1 may include a first line LN1. The first line LN1 may be formed by etching a metal plate or may be formed by an ink-jet printing method. The first line LN1 may define a plurality of first unit cells AXP1. Each of the plurality of first unit cells AXP1 corresponds to an auxetic pattern. The first unit cell AXP1 has a closed curve shape, and an opening OP1 is defined in the first unit cell AXP1 such that the first auxetic structure AX1 may be a net structure.

In FIGS. 5 and 6A, an auxetic pattern having a star shape is illustrated as the first unit cell AXP1. The star-shaped auxetic pattern illustrated in FIG. 6A may have a Poisson's ratio of −0.1. The Poisson's ratio may be determined depending on the shape of the auxetic pattern.

The first unit cell AXP1 may include a plurality of first protrusions PP1 and a plurality of first depressions CP1. In this embodiment, a star-shaped auxetic pattern including three first protrusions PP1 and three first depressions CP1 is illustrated as an example.

According to an embodiment of the present disclosure, a star-shaped auxetic pattern including a larger number of first protrusions PP1 and a larger number of first depressions CP1 may be applied to the first unit cell AXP1.

The plurality of first protrusions PP1 may have the same maximum separation distance from the center C1 of the first unit cell AXP1. The plurality of first depressions CP1 may have the same minimum separation distance from the center C1 of the first unit cell AXP1. The first depressions CP1 of the first unit cell AXP1 may share the same portion of the first line LN1 with the first protrusions PP1 of another unit cell adjacent to the first unit cell AXP1.

In this embodiment, the three first protrusions PP1 and the three first depressions CP1 may alternate with one another in the clockwise direction. The three first protrusions PP1 may be arranged at a constant angle with the center C1 of the first unit cell AXP1 as a rotational axis. One first protrusion PP1 may overlap another first protrusion PP1 when the first unit cell AXP1 is rotated about the center C1 by the constant angle. The three first depressions CP1 may be arranged at the constant angle with the center C1 of the first unit cell AXP1 as a rotational axis. One first depression CP1 may overlap another first depression CP1 when the first unit cell AXP1 is rotated about the center C1 by the constant angle.

A first pitch PT1 will be described based on two first unit cells AXP1 adjacent to each other. The distance between the first protrusion PP1 and the first depression CP1 disposed on the same line may be defined as the first pitch PT1. The first line LN1 may have a thickness of 10 μm to 500 μm in the third direction DR3. The first line LN1 may have a line width of 10 μm to 90 μm in a direction parallel to a plane defined by the first and second directions DR1 and DR2.

Referring to FIGS. 5 and 6B, the second auxetic structure AX2 may include a second line LN2. The second auxetic structure AX2 may be formed by the same method as one of the methods of forming the first auxetic structure AX1.

The second line LN2 may define a plurality of second unit cells AXP2 (or, second auxetic unit cells). Each of the plurality of second unit cells AXP2 corresponds to an auxetic pattern. The second unit cell AXP2 has a closed curve shape, and an opening OP2 is defined in the second unit cell AXP2 such that the first auxetic structure AX1 may be a net structure.

In FIGS. 5 and 6B, the second unit cell AXP2 that has the same shape as the first unit cell AXP1, but has an area different from an area of the first unit cell AXP1 is illustrated. The second unit cell AXP2 may also be a star-shaped auxetic pattern and may have a Poisson's ratio of −0.1. The second unit cell AXP2 including three second protrusions PP2 and three second depressions CP2 is illustrated as an example.

A second pitch PT2 will be described based on two second unit cells AXP2 adjacent to each other. The distance between the second protrusion PP2 and the second depression CP2 disposed on the same line may be defined as the second pitch PT2. The second line LN2 may have a thickness of 10 μm to 500 μm in the third direction DR3. The second line LN2 may have a line width of 10 μm to 90 μm in a direction parallel to a plane defined by the first and second directions DR1 and DR2. The first line LN1 and the second line LN2 may have the same thickness and line width. The second pitch P2 may be greater than the first pitch P1.

Referring to FIGS. 7A and 7B, since the first line LN1 and the second line LN2 have different pitches, the second line LN2, when viewed from above the plane, may overlap the openings OP1 of at least some of the first unit cells AXP1. FIG. 7B illustrates an example that the second line LN2 corresponding to one second unit cell AXP2 overlaps the openings OP1 of ten first unit cells in a plan view. However, the number of first unit cells overlapping one second unit cell AXP2 in a plan view may vary depending on the position of the second unit cell AXP2.

Since the second line LN2 overlaps the openings OP1 of the at least some of the first unit cells in a plan view, the aperture ratio in the separation area SD may be decreased. Here, the aperture ratio refers to the ratio between the area in which the first line LN1 and the second line LN2 are not disposed in the separation area SD and the total area of the separation area SD.

As illustrated in FIGS. 5 and 6A to 7B, the stress control layer SRL may include the first auxetic structure AX1 and the second auxetic structure AX2 having different pitches. Accordingly, the impact resistance and the surface quality of the display device DD may be effectively improved.

In Table 1 below, the pen drop characteristics and surface qualities of display devices according to comparative examples and display devices according to embodiments of the present disclosure are compared. The pen drop characteristics are values obtained by measuring the pen drop heights at which defects occur in the display devices when pens are dropped from above the front surfaces of the display devices. The higher the pen drop height, the better the impact resistance. The surface qualities are values obtained by measuring the flatness of the front surfaces of the display devices through an Optimap Phase Stepped Deflectometry (“PSD”) coating surface measurement analyzer.

The comparative examples and the embodiments in Table 1 differ from one another only in the structures of the stress control layers SRL among the stack structures of the display devices. The structures of the stress control layers SRL in the comparative examples and the embodiments are listed in Table 2.

TABLE 1

| | Compara- | Compara- | Compara- | Compara- | | Compara- | |
|---|---|---|---|---|---|---|---|
| | tive | tive | tive | tive | | tive | |
| | Example | Example | Example | Example | Embodi- | Example | Embodi- |
| | 1 | 2 | 3 | 4 | ment 1 | 5 | ment 2 |
| Pen | 6 cm | 4 cm | 6 cm | 8 cm | 10 cm | 9 cm | 12 cm |
| Drop | | | | | | | |
| Surface | 1.82 | 1.7 | — | 0.51 | 0.57 | 0.55 | 0.50 |
| Quality | | | | | | | |
| (Kc) | | | | | | | |

TABLE 2

| | Compara- | Compara- | Compara- | Compara- | | Compara- | |
|---|---|---|---|---|---|---|---|
| | tive | tive | tive | tive | | tive | |
| | Example | Example | Example | Example | Embodi- | Example | Embodi- |
| | 1 | 2 | 3 | 4 | ment 1 | 5 | ment 2 |
| Pitch of | X | 600 μm | 600 μm | 1200 μm | 450 μm | 1000 μm | 450 μm |
| First | | | | | | | |
| Auxetic | | | | | | | |
| Structure | | | | | | | |
| Thickness/Line | X | 50 μm/ | 50 μm/ | 50 μm/ | 50 μm/ | 50 μm/ | 50 μm/ |
| Width of | | 60 μm | 60 μm | 80 μm | 80 μm | 80 μm | 80 μm |
| First | | | | | | | |
| Auxetic | | | | | | | |
| Structure | | | | | | | |
| Pitch of | X | X | 600 μm | 450 μm | 1200 μm | 450 μm | 1000 μm |
| Second | | | | | | | |
| Auxetic | | | | | | | |
| Structure | | | | | | | |
| Thickness/Line | X | X | 50 μm/ | 50 μm/ | 50 μm/ | 50 μm/ | 50 μm/ |
| Width of | | | 60 μm | 80 μm | 80 μm | 80 μm | 80 μm |
| Second | | | | | | | |
| Auxetic | | | | | | | |
| Structure | | | | | | | |
| Aperture | — | 74% | 74% | 37% | 37% | 35% | 35% |
| Ratio | | | | | | | |

In Table 1 and Table 2, comparative example 1 does not include an auxetic structure and includes a black polyimide film disposed at the corresponding 5 position instead of one auxetic structure when compared to comparative example 2. Referring to Table 1 and Table 2, it can be seen that the pen drop heights in comparative examples 3 to 5 including two auxetic structures are greater than the pen drop height in comparative example 2 including one auxetic structure. The same effect is obtained when embodiment 1 and embodiment 2 are compared with comparative example 2. It can be seen that an increase in the number of stacked auxetic structures leads to an improvement in impact resistance. Here, the auxetic structures used in comparative examples and embodiment include the same materials.

It can be seen that when the stress control layer includes two identical auxetic structures as in comparative example 3, two unit cells overlap each other so that the aperture ratio is not decreased, and the increase in pen drop height is relatively small. In addition, it can be seen that when the stress control layer includes two auxetic structures having different pitches as in comparative examples 4 and 5 and embodiments 1 and 2, the pen drop height is further increased due to a decrease in aperture ratio.

Additionally, when comparative example 4 and embodiment 1 are compared with each other and comparative example 5 and embodiment 2 are compared with each other, it can be seen that the pen drop height is relatively large when the auxetic structure having a small pitch is disposed above the auxetic structure having a large pitch. This is because the auxetic structure having the small pitch is disposed closer to the display panel than the auxetic structure having the large pitch to better withstand external impact. The auxetic structure having the small pitch has a higher modulus than the auxetic structure having the large pitch, and when the auxetic structure having the higher modulus is disposed adjacent to the display panel, the auxetic structure better withstands external impact.

When the stress control layer SRL includes two auxetic structures having different pitches, the aperture ratio in the separation area SD of FIG. 4B is decreased. Accordingly, the stress control layer SRL may provide a relatively flat surface to a component disposed above the stress control layer SRL (e.g., the fourth adhesive layer ADL4 of FIG. 3) or a component disposed below the stress control layer SRL (e.g., the second adhesive layer ADL2 of FIG. 3), thereby increasing the surface quality.

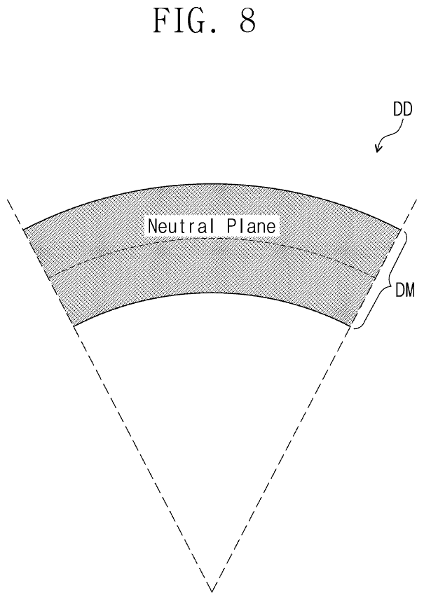

FIG. 8 is a sectional view illustrating a neutral plane formed in the display device DD in the second mode according to an embodiment of the present disclosure.

In FIG. 8, only the display module DM in the cross-sectional structure of the display device DD illustrated in FIG. 3 is briefly illustrated. When the display device DD is deformed to form a curved surface in the second mode, the neural plane may be formed in the display module DM. The neutral plane may be a plane where tensile stress and compressive stress are balanced, and the location of the neutral plane may be changed depending on the stack structure of the display device DD.

High stress may be applied to a component disposed far away from the neutral plane, and therefore the corresponding component may be subjected to large deformation. In the second mode of the display device DD according to an embodiment, since the first auxetic structure AX1 may be disposed closer to the display module DM than the second auxetic structure AX2, compressive stress greater than the compressive stress applied to the first auxetic structure AX1 may be applied to the second auxetic structure AX2 of FIG. 3. Since the second auxetic structure AX2 includes unit cells having a larger pitch than the unit cells in the first auxetic structure AX1 as described with reference to FIGS. 6A to 7B, the second auxetic structure AX2 has a higher elongation than the first auxetic structure AX1. Accordingly, the second auxetic structure AX2 may withstand relatively high compressive stress without defects compared to the first auxetic structure AX1.

Table 3 below shows the effective modulus, the elongation, and the aperture ratio depending on the thickness, line width, and pitch of an auxetic structure.

TABLE 3

| Thickness/Line Width/Pitch | Effective | | | Aperture |
|---|---|---|---|---|
| of Auxetic structure | Modulus | | Elongation | Ratio |
| 50 μm/80 μm/450 μm | 949 | MPa | 87% | 45% |
| 50 μm/80 μm/1000 μm | 76 | MPa | 124% | 73% |
| 50 μm/80 μm/1200 μm | 30 | MPa | 133% | 77% |

When the second auxetic structure AX2 has a higher elongation than the first auxetic structure AX1, this means that the second auxetic structure AX2 has a lower elastic modulus than the first auxetic structure AX1. The first auxetic structure AX1 may have an elastic modulus of 200 MPa to 1 GPa, and the second auxetic structure AX2 may have an elastic modulus of 20 MPa to 200 MPa. Here, the first auxetic structure AX1 and the second auxetic structure AX2 include the same materials, while sizes (e.g., thickness, line width, or area of each cell) of them are different from each other. The difference in physical characteristics (e.g., Poisson's ratio, elastic modulus, etc.) between the first auxetic structure AX1 and the second auxetic structure AX2 are caused by the size differences.

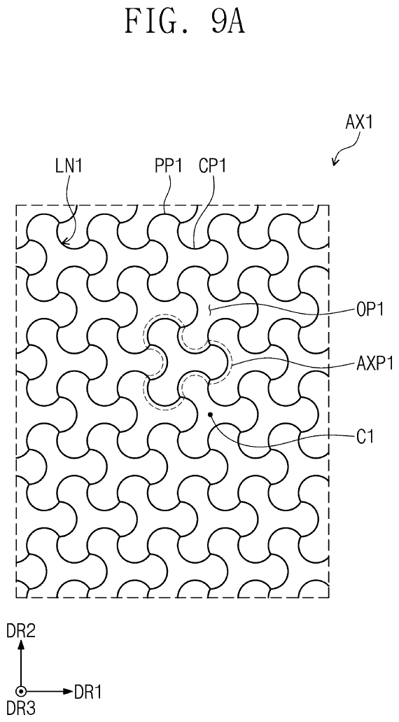

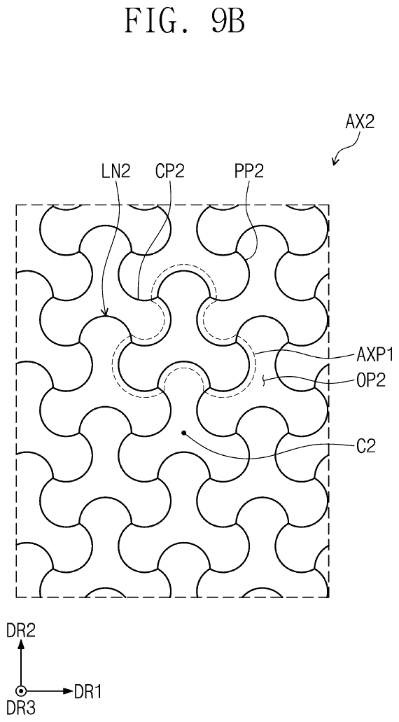

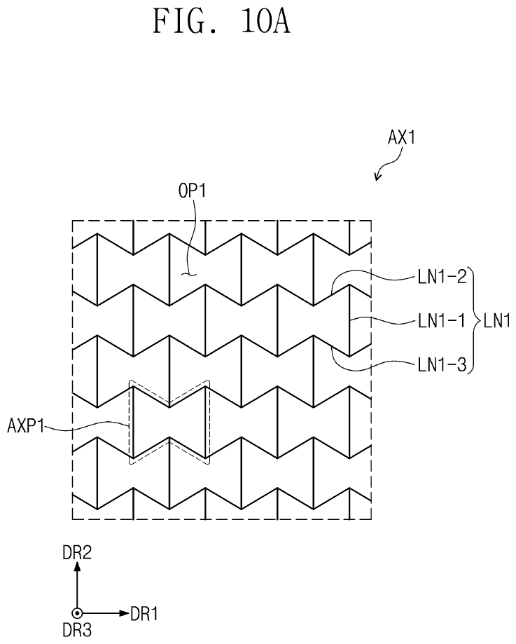

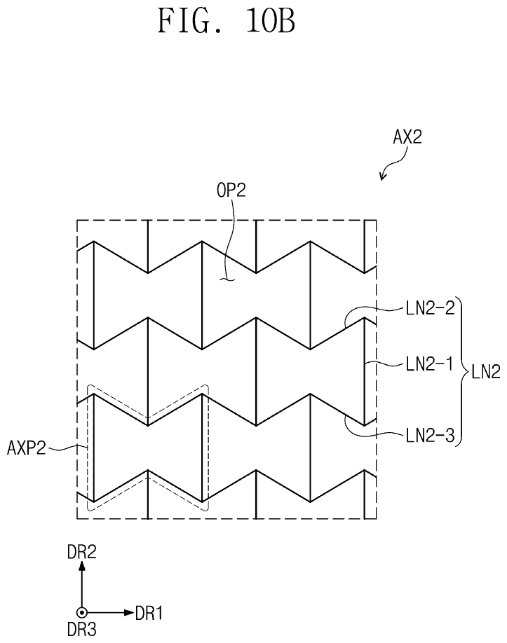

FIG. 9A is a plan view illustrating the first auxetic structure AX1 according to an embodiment of the present disclosure. FIG. 9B is a plan view illustrating the second auxetic structure AX2 according to an embodiment of the present disclosure. FIG. 10A is a plan view illustrating the first auxetic structure AX1 according to an embodiment of the present disclosure. FIG. 10B is a plan view illustrating the second auxetic structure AX2 according to an embodiment of the present disclosure.

The following description will be focused on the difference between the stress control layer SRL illustrated in FIGS. 9A and 9B and the stress control layer SRL described with reference to FIGS. 5 to 7B. The second unit cells AXP2 of FIG. 9B may have a shape in which the second unit cells AXP2 of FIG. 7B are rotated by a certain angle. However, since the second unit cells AXP2 of FIG. 9B have the same shape and area as the second unit cells AXP2 of FIG. 6B, the second auxetic structure AX2 of FIG. 9B may have the same elastic modulus as the second auxetic structure AX2 of FIG. 6B.

When the first auxetic structure AX1 of FIG. 9A and the second auxetic structure AX2 of FIG. 9B are disposed to overlap each other in a plan view, the same effect as the effect obtained when the first auxetic structure AX1 of FIG. 7A and the second auxetic structure AX2 of FIG. 7B are disposed to overlap each other may be obtained.

FIGS. 10A and 10B illustrate the first auxetic structure AX1 and the second auxetic structure AX2 that include an auxetic pattern having a re-entrant shape.

The first auxetic structure AX1 and the second auxetic structure AX2 of FIGS. 10A and 10B may have a Poisson's ratio of −0.8. The first auxetic structure AX1 may include the first line LN1, and the second auxetic structure AX2 may include the second line LN2.

The first line LN1 may include first-first elements LN1-1, first-second elements LN1-2 extending in a direction different from the direction in which the first-first elements LN1-1 extend, and first-third elements LN1-3 extending in a direction different from the directions in which the first-first elements LN1-1 and the first-second elements LN1-2 extend.

Each of the first-first elements LN1-1 may be disposed between the first-second elements LN1-2 and the first-third elements LN1-3 adjacent to each other in the first direction DR1. A first-third element LN1-3 extends from one end of a first-first element LN1-1 to the left, and a first-second element LN1-2 extends from the one end of the first-first element LN1-1 to the right. A first-third element LN1-3 extends from an opposite end of the first-first element LN1-1 to the left, and a first-second element LN1-2 extends from the opposite end of the first-first element LN1-1 to the right.

Two first-first elements LN1-1, two first-second elements LN1-2, and two first-third elements LN1-3 define a first unit cell AXP1. The two first-first elements LN1-1 are spaced apart from each other in the first direction DR1. The distance between the two first-first elements LN1-1 spaced apart from each other in the first direction DR1 may correspond to the pitch of the first unit cell AXP1.

One first-second element LN1-2 and one first-third element LN1-3 are disposed between first ends of the two first-first elements LN1-1 spaced apart from each other, and one first-second element LN1-2 and one first-third element LN1-3 are disposed between second ends of the two first-first elements LN1-1 spaced apart from each other. The first-second element LN1-2 and the first-third element LN1-3 may be considered to extend from each other and may form a concave area of the first unit cell AXP1. The first unit cell AXP1 has a closed curve shape, and an opening OP1 is defined in the first unit cell AXP1.

The second line LN2 defining the second unit cell AXP2 having an increased area may also include second-first elements LN2-1, second-second elements LN2-2, and second-third elements LN2-3. The second-first elements LN2-1 may correspond to the first-first elements LN1-1, the second-second elements LN2-2 may correspond to the first-second elements LN1-2, and the second-third elements LN2-3 may correspond to the first-third elements LN1-3.

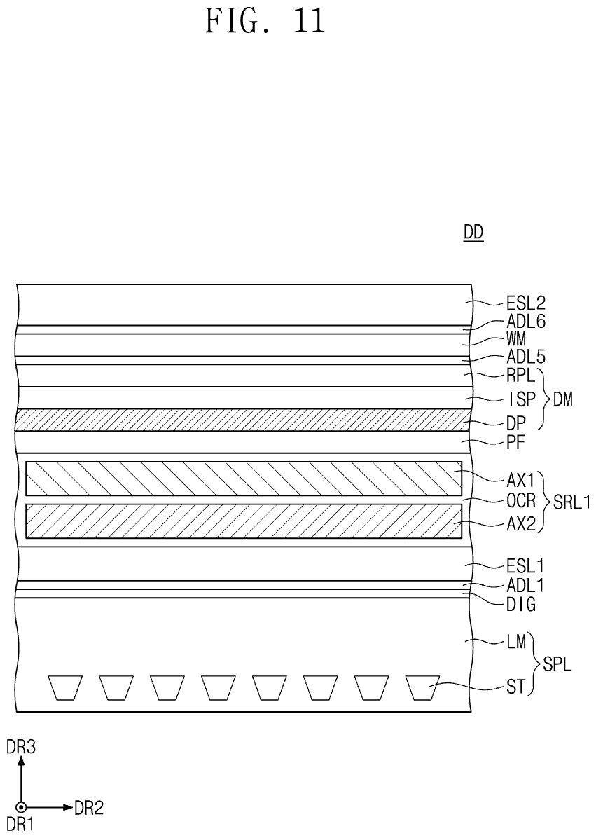

FIG. 11 is a sectional view of the display device DD according to another embodiment of the present disclosure. The following description will be focused on the difference from the display device DD of FIG. 3, and detailed description of the same components refers to the description of FIG. 3.

A stress control layer SRL1 may include the first auxetic structure AX1, the second auxetic structure AX2, and an adhesive layer OCR. The first auxetic structure AX1 and the second auxetic structure AX2 may be impregnated in the adhesive layer OCR. In other words, the first auxetic structure AX1 and the second auxetic structure AX2 may be completely surrounded by the adhesive layer OCR. The first auxetic structure AX1 and the second auxetic structure AX2 may be spaced apart from each other by a constant gap in the third direction DR3 and may be located inside the adhesive layer OCR. The adhesive layer OCR may surround all surfaces of the first auxetic structure AX1 and the second auxetic structure AX2. The adhesive layer OCR may replace the second adhesive layer ADL2, the third adhesive layer ADL3, and the fourth adhesive layer ADL4 of FIG. 3.

The adhesive layer OCR may be formed of an optically clear resin in an amorphous liquid form. The adhesive layer OCR may be formed of an acrylic adhesive material, a silicone-based adhesive material, and a urethane-based adhesive material. However, without being limited thereto, the adhesive layer OCR may be formed of adhesive materials having various shapes and materials.

The adhesive layer OCR may provide flat upper and lower surfaces even though the first auxetic structure AX1 and the second auxetic structure AX2 are disposed inside the adhesive layer OCR. Accordingly, the surface quality of the display device DD may be improved.

A method of forming the stress control layer SRL1 including the adhesive layer OCR of FIG. 11 is as follows. A first optically clear resin layer is formed on one of the upper surface of the first elastic layer ESL1 and the lower surface of the display panel protection layer PF. A corresponding one of the first auxetic structure AX1 and the second auxetic structure AX2 is impregnated in the first optically clear resin layer. A second optically clear resin layer is formed on the first optically clear resin layer to cover the auxetic structure. Another auxetic structure is impregnated in the second optically clear resin layer. A third optically clear resin layer is formed on the second optically clear resin layer to cover the other auxetic structure. The other one of the upper surface of the first elastic layer ESL1 and the lower surface of the display panel protection layer PF is bonded to the third optically clear resin layer.

The first to third optically clear resin layers may be cured by a curing process to form the adhesive layer OCR of FIG. 11. The curing process is not limited to a single process. The curing process may be performed after the one auxetic structure is impregnated in the first optically clear resin layer and the other auxetic structure is impregnated in the second optically clear resin layer.

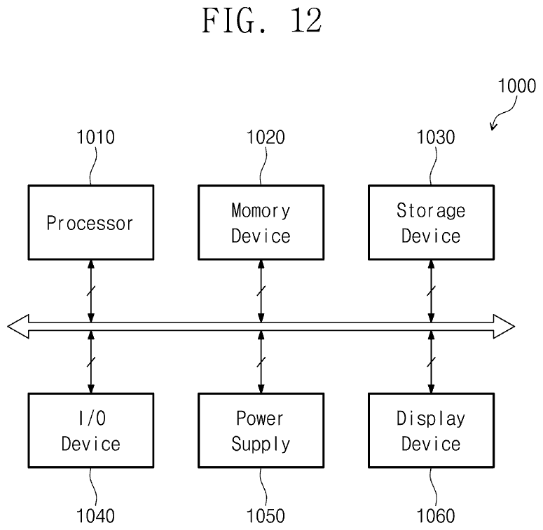

FIG. 12 is a block diagram illustrating an electronic device according to an embodiment.

Referring to FIG. 12, in an embodiment, an electronic device 1000 may include a processor 1010, a memory device 1020, a storage device 1030, an input/output (“I/O”) device 1040, a power supply 1050, and a display device 1060. Here, the display device 1060 may correspond to the display device DD of FIGS. 1A to 3 and 11. The electronic device 1000 may further include a plurality of ports for communicating with a video card, a sound card, a memory card, a universal serial bus (“USB”) device, or the like. In an embodiment, the electronic device 1000 may be implemented as a television. In another embodiment, the electronic device 1000 may be implemented as a smart phone. However, embodiments are not limited thereto, in another embodiment, the electronic device 1000 may be implemented as a cellular phone, a video phone, a smart pad, a smart watch, a tablet personal computer (“PC”), a car navigation system, a computer monitor, a laptop, a head disposed (e.g., mounted) display (“HMD”), or the like.

The memory device 1020 may store data for operations of the electronic device 1000. In an embodiment, the memory device 1020 may include at least one non-volatile memory device such as an erasable programmable read-only memory (“EPROM”) device, an electrically erasable programmable read-only memory (“EEPROM”) device, a flash memory device, a phase change random access memory (“PRAM”) device, a resistance random access memory (“RRAM”) device, a nano floating gate memory (“NFGM”) device, a polymer random access memory (“PoRAM”) device, a magnetic random access memory (“MRAM”) device, a ferroelectric random access memory (“FRAM”) device, or the like, and/or at least one volatile memory device such as a dynamic random access memory (“DRAM”) device, a static random access memory (“SRAM”) device, a mobile DRAM device, or the like.

The processor 1010 may perform various computing functions. In an embodiment, the processor 1010 may be a microprocessor, a central processing unit (“CPU”), an application processor (“AP”), or the like. The processor 1010 may be coupled to other components via an address bus, a control bus, a data bus, or the like. In an embodiment, the processor 1010 may be coupled to an extended bus such as a peripheral component interconnection (“PCI”) bus.

In an embodiment, the storage device 1030 may include a solid state drive (“SSD”) device, a hard disk drive (“HDD”) device, a CD-ROM device, or the like. In an embodiment, the I/O device 1040 may include an input device such as a keyboard, a keypad, a mouse device, a touchpad, a touch-screen, or the like, and an output device such as a printer, a speaker, or the like.

The power supply 1050 may provide power for operations of the electronic device 1000. The power supply 1050 may provide power to the display device 1060. The display device 1060 may be coupled to other components via the buses or other communication links. In an embodiment, the display device 1060 may be included in the I/O device 1040.

According to the present disclosure, the impact resistance of the display device may be effectively improved. This is because the auxetic structure having the small pitch is disposed closer to the display panel than the auxetic structure having the large pitch.

In addition, even though a folding operation or a rolling operation is repeated, defects in the display device may be effectively reduced. This is because the auxetic structure having high elongation characteristics is disposed at the position where stress significantly acts.

While the present disclosure has been described with reference to embodiments thereof, it will be apparent to those of ordinary skill in the art that various changes and modifications may be made thereto without departing from the spirit and scope of the present disclosure as set forth in the following claims.

What is claimed is:

1. A display device comprising:
a display panel;
an upper member disposed above the display panel;
a first auxetic structure disposed below the display panel, the first auxetic structure including first unit cells; and
a second auxetic structure disposed below the first auxetic structure, the second auxetic structure including second unit cells,
wherein the first unit cells of the first auxetic structure have a smaller pitch than the second unit cells of the second auxetic structure.

2. The display device of claim 1, further comprising:
an adhesive layer disposed between the first auxetic structure and the second auxetic structure to bond the first auxetic structure and the second auxetic structure,
wherein the adhesive layer has a lower elastic modulus than each of the first auxetic structure and the second auxetic structure.

3. The display device of claim 1, wherein the display panel provides a display surface defined by a first direction and a second direction, and
wherein in a first mode of the display device, the display surface provides a flat surface, and in a second mode of the display device, at least a partial area of the display surface provides a curved surface having a certain curvature with respect to a reference axis.

4. The display device of claim 3, further comprising:
a support layer disposed below the second auxetic structure,
wherein the support layer includes a plurality of support sticks parallel to the reference axis, and
wherein in the first mode, the plurality of support sticks are arranged in a direction crossing the reference axis.

5. The display device of claim 1, wherein the first unit cells have each a same shape as and a different area from each the second unit cells.

6. The display device of claim 1, wherein the first auxetic structure includes a first line, and the second auxetic structure includes a second line, and
wherein the first line defines the first unit cells, each of which defines an opening therein.

7. The display device of claim 6, wherein the first line has substantially the same line width as the second line, and the first line has substantially the same thickness as the second line.

8. The display device of claim 6, wherein the second line overlaps the openings of at least some of the first unit cells in a plan view.

9. The display device of claim 6, wherein the display panel includes a display area where a pixel is disposed and a non-display area where a pixel is not disposed, and
wherein the first auxetic structure and the second auxetic structure overlap an entirety of the display area in a plan view.

10. The display device of claim 1, further comprising:
an adhesive layer disposed below the display panel,
wherein the first auxetic structure and the second auxetic structure are impregnated in the adhesive layer.

11. A display device comprising:
a display panel;
an upper member disposed above the display panel;
a first auxetic structure disposed below the display panel; and
a second auxetic structure disposed below the first auxetic structure,
wherein the second auxetic structure has a lower elastic modulus than the first auxetic structure.

12. The display device of claim 11, wherein the first auxetic structure has an elastic modulus of 200 megapascals (MPa) to 1 gigapascal (GPa), and
wherein the second auxetic structure has an elastic modulus of 20 MPa to 200 MPa.

13. The display device of claim 11, further comprising:
an adhesive layer disposed between the first auxetic structure and the second auxetic structure to bond the first auxetic structure and the second auxetic structure,
wherein the adhesive layer has a lower elastic modulus than each of the first auxetic structure and the second auxetic structure.

14. The display device of claim 11, further comprising:
a support layer disposed below the second auxetic structure,
wherein the support layer includes a plurality of support sticks, and
wherein the plurality of support sticks are arranged in a direction crossing a direction in which the plurality of support sticks extend.

15. The display device of claim 11, wherein the first auxetic structure includes a first line, and the second auxetic structure includes a second line,
wherein the first line defines first unit cells, each of which defines a first opening therein, and
wherein the second line defines second unit cells, each of which defines a second opening therein.

16. The display device of claim 15, wherein the first unit cells have each a same shape as and a different area from and each the second unit cells.

17. The display device of claim 15, wherein the first line has substantially the same line width and thickness as the second line.

18. The display device of claim 15, wherein the second line overlaps the first openings of at least some of the first unit cells in a plan view.

19. The display device of claim 11, wherein the display panel includes a display area where a pixel is disposed and a non-display area where a pixel is not disposed, and
wherein the first auxetic structure and the second auxetic structure overlap an entirety of the display area in a plan view.

20. An electronic device comprising:
a display device; and
a power supply configured to provide power to the display device, wherein the display device comprises:
a display panel;
an upper member disposed above the display panel;
a first auxetic structure disposed below the display panel; and
a second auxetic structure disposed below the first auxetic structure,
wherein the second auxetic structure has a lower elastic modulus than the first auxetic structure.
